(19) United States
(12) Patent Application Publication
(10) Pub. No.: US 2024/0329681 A1
(43) Pub. Date: Oct. 3, 2024

(54) CONSTANT CURRENT CIRCUIT, TIMER CIRCUIT, ONE-SHOT MULTIVIBRATOR CIRCUIT, AND SEMICONDUCTOR INTEGRATED CIRCUIT

(71) Applicant: ROHM CO., LTD., Kyoto (JP)

(72) Inventor: Naohiro NOMURA, Kyoto (JP)

(21) Appl. No.: 18/616,657

(22) Filed: Mar. 26, 2024

(30) Foreign Application Priority Data
Mar. 28, 2023 (JP) 2023-052369

(51) Int. Cl. G05F 3/26; H03K 3/0232; H10B 20/25

(52) U.S. Cl. CPC G05F 3/262; H03K 3/0232; H10B 20/25

(57) ABSTRACT

A constant current circuit includes: a first current mirror circuit connected to a first line serving as one of a power supply line and a ground line; a series connection circuit provided between a second line, which serves as the other of the power supply line and the ground line, and an input node of the first current mirror circuit, and including a resistor and a reference transistor, which is a MOSFET (Metal Oxide Semiconductor Field Effect Transistor) with a gate and a drain connected to each other; and a second current mirror circuit connected to the second line and configured to generate a first current by folding back a reference current, wherein the constant current circuit is capable of outputting a current corresponding to a third current, which is a difference between a second current and the first current respectively outputted from the first and second current mirror circuits.

### CROSS-REFERENCE TO RELATED APPLICATION

The present invention claims priority under 35 U.S.C. § 119 to Japanese Patent Application No. 2023-052369, filed on Mar. 28, 2023, the entire contents of which are incorporated herein by reference.

### TECHNICAL FIELD

The present disclosure relates to a constant current circuit.

### BACKGROUND

Generally, a semiconductor integrated circuit is equipped with a reference current source for generating a constant reference current that does not depend on a power supply voltage or the like. This reference current is copied and distributed as a bias current to various circuit blocks within the semiconductor integrated circuit.

In general, a current mirror circuit is used to copy a reference current. A bias current generated by the current mirror circuit is preferred in many applications because it does not depend on the power supply voltage.

### BRIEF DESCRIPTION OF DRAWINGS

The accompanying drawings, which are incorporated in and constitute a part of the specification, illustrate embodiments of the present disclosure.

FIG. 1 is a circuit diagram of a constant current circuit according to a first embodiment.

FIG. 2 is a circuit diagram of a constant current circuit according to a second embodiment.

FIG. 3 is a circuit diagram of a constant current circuit according to a third embodiment.

FIG. 4 is a circuit diagram of a constant current circuit according to a fourth embodiment.

FIG. 5 is a circuit diagram of a timer circuit including a constant current circuit.

FIG. 6 is a circuit diagram of a one-shot multivibrator circuit including a constant current circuit.

FIG. 7 is a diagram showing power supply voltage dependence of an output current I of the constant current circuit.

FIG. 8A and FIG. 8B are operation waveform diagrams of the one-shot multivibrator circuit when operated with a current of a comparative technique (ii) in FIG. 7.

FIG. 9A and FIG. 9B are operation waveform diagrams of the one-shot multivibrator circuit when operated with a current of embodiment (i) in FIG. 7.

FIG. 10 is a block diagram of a semiconductor integrated circuit including the one-shot multivibrator circuit.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Summary of some exemplary embodiments of the present disclosure will be described. This summary is intended to provide a simplified description of some concepts of one or more embodiments as a prelude to the detailed description presented later in order to provide a basic understanding of the embodiments, and is not intended to limit the scope of the present disclosure. This summary is not an exhaustive overview of all possible embodiments and is not intended to define key elements of all embodiments or to delineate the scope of any or all aspects. For the sake of convenience, the expression “one embodiment” may be used to refer to one embodiment (example or modification) or multiple embodiments (examples or modifications) disclosed in this specification.

### Summary of Embodiments

A constant current circuit according to one embodiment includes: a first current mirror circuit connected to a first line serving as one of a power supply line and a ground line; a series connection circuit provided between a second line, which serves as the other of the power supply line and the ground line, and an input node of the first current mirror circuit, and including a resistor and a reference transistor, which is a MOSFET (Metal Oxide Semiconductor Field Effect Transistor) with a gate and a drain connected to each other; and a second current mirror circuit connected to the second line and configured to generate a first current I₁ by folding back a reference current I_{REF}. The constant current circuit is configured to be capable of outputting a current corresponding to a third current I₃, which is a difference between a second current I₂ outputted from the first current mirror circuit and the first current I₁ outputted from the second current mirror circuit.

A current I_{R} flowing through the resistor is I_{R}=(V_{DD}−Vgs1−Vgs2)/R. Vgs1 is a gate-source voltage of the reference transistor, and Vgs2 is a gate-source voltage of the MOSFET on an input side of the first current mirror circuit.

If a current amplification factor of the first current mirror circuit is assumed to be x, then the second current I₂ is I₂=x·I_{R}. If a current amplification factor of the second current mirror circuit is assumed to be α, the first current I₁ is I₁=α·I_{REF}. Therefore, the third current I₃ is I₃=I₁−I₂=α·I_{REF}−x·I_{R}=α·I_{REF}−x·(V_{DD}−Vgs1−Vgs2)/R. Accordingly, by adjusting α and x, it is possible to generate a constant current I₃ having desired dependence and polarity with respect to the power supply voltage V_{DD}.

In one embodiment, the second current mirror circuit may generate a fourth current I₄ by folding back the reference current I_{REF}. The constant current circuit may further include a third current mirror circuit configured to fold back the fourth current I₄ to generate a fifth current I₅. The constant current circuit may be configured to be capable of outputting a current corresponding to a sixth current I₆ which is a difference between the third current I₃ and the fifth current I₅.

In one embodiment, the second current mirror circuit may generate a seventh current I₇ by folding back the reference current I_{REF}. The constant current circuit may further include a fourth current mirror circuit configured to fold back the sixth current I₆ to generate an eighth current I₈. The constant current circuit may be configured to be capable of outputting a current corresponding to a ninth current I₉ which is a difference between the seventh current I₇ and the eighth current I₈.

In one embodiment, the constant current circuit may further include a fifth current mirror circuit configured to fold back the ninth current I₉ to generate a tenth current I₁₀. The constant current circuit may be configured to be capable of outputting a current corresponding to the tenth current I₁₀.

In one embodiment, the constant current circuit may further include a sixth current mirror circuit configured to fold back the tenth current I₁₀ to generate an eleventh current I₁₁. The constant current circuit may be configured to be capable of outputting a current corresponding to the eleventh current I₁₁.

A timer circuit according to one embodiment may include a capacitor, any one of the above-described constant current circuit configured to charge the capacitor, and an inverter configured to receive a voltage of the capacitor. A threshold value of the inverter is changed depending on a power supply voltage. By allowing an output current of the constant current circuit to have power supply voltage dependence so as to follow the change in the threshold value, it is possible to perform timer setting that does not depend on the power supply voltage.

A one-shot multivibrator circuit according to one embodiment may include the above-described timer circuit. This allows a same pulse width to be outputted regardless of the power supply voltage.

A semiconductor integrated circuit according to one embodiment may include a one-time memory circuit including a fuse, and a trimming circuit including the above-described one-shot multivibrator circuit configured to receive a pulse signal.

### Embodiments

Hereinafter, preferred embodiments will be described with reference to the drawings. Identical or equivalent components, members, and processes shown in each drawing are designated by like reference numerals, and redundant explanations will be omitted as appropriate. Further, the embodiments are exemplary and do not limit the present disclosure. All features described in the embodiments and combinations thereof are not necessarily essential to the present disclosure.

In the present disclosure, “a state where a member A is connected to a member B” includes a case where the member A and the member B are physically and directly connected or even a case where the member A and the member B are indirectly connected through any other member that does not affect an electrical connection state between the members A and B or does not impair functions and effects achieved by combinations of the members A and B.

Similarly, “a state where a member C is connected (installed) between a member A and a member B” includes a case where the member A and the member C or the member B and the member C are indirectly connected through any other member that does not affect an electrical connection state between the members A and C or the members B and C or does not impair functions and effects achieved by combinations of the members A and C or the members B and C, in addition to a case where the member A and the member C or the member B and the member C are directly connected.

### Embodiments

### First Embodiment

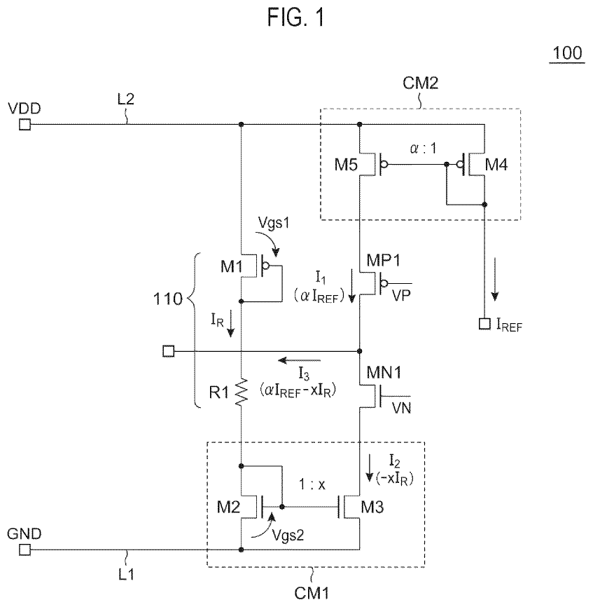

FIG. 1 is a circuit diagram of a constant current circuit 100 according to a first embodiment. The constant current circuit 100 includes a reference transistor M1, a reference resistor R1, a first current mirror circuit CM1, and a second current mirror circuit CM2.

The first current mirror circuit CM1 is connected to a first line L1, which is one of a power supply line VDD and a ground line GND. The current mirror circuit CM1 includes NMOS transistors M2 and M3, and has a current amplification factor (current mirror ratio) x. The current mirror ratio may be larger than 1, may be smaller than 1, or may be 1.

A series connection circuit 110 including a reference resistor R1 and a reference transistor M1 is provided between a second line L2, which is the other of the power supply line V_{DD} and the ground line GND, and an input node of the first current mirror circuit CM1. In this example, the first line L1 is the ground line GND, and the second line L2 is the power supply line V_{DD}. The reference transistor M1 is a MOSFET (Metal Oxide Semiconductor Field Effect Transistor) whose gate and drain are connected, and functions as a voltage clamp element.

The second current mirror circuit CM2 is connected to the second line L2 and is configured to fold back a reference current I_{REF} to generate a first current I₁. The second current mirror circuit CM2 includes PMOS transistors M4 and M5, and has a current amplification factor α. The reference current I_{REF} is generated by a reference current source (not shown) and is a constant current that does not depend on a power supply voltage.

The constant current circuit 100 is configured to be capable of outputting a current corresponding to a third current I₃ which is a difference between a second current I₂ outputted from the first current mirror circuit CM1 and the first current I₁ outputted from the second current mirror circuit CM2. The term “output” may include a case where a direction of a current is a source (outgoing) and a case where the direction of the current is a sink (incoming). The current is expressed as positive in the direction of the source and the current is expressed as negative in the direction of the sink.

Bias voltages VN and VP generated by a cascode bias capacitor circuit (not shown) are applied to gates of transistors MN1 and MP1, respectively.

A current I_{R} flowing through the resistor R1 is I_{R}=(V_{DD}−Vgs1−Vgs2)/R. Vgs1 is a gate-source voltage of the reference transistor M1, and Vgs2 is a gate-source voltage of the MOSFET on an input side of the first current mirror circuit CM1.

By using the current amplification factor x of the first current mirror circuit, the second current I₂ is expressed as I₂=x·I_{R}. By using the current amplification factor α of the second current mirror circuit, the first current I₁ is expressed as I₁=α·I_{REF}. Therefore, the third current I₃ is expressed as I₃=I₁−I₂=α·I_{REF}−x·I_{R}=α·I_{REF}−x·(V_{DD}−Vgs1−Vgs2)/R. Accordingly, by adjusting α and x, it is possible to generate a constant current I₃ having desired dependence and polarity with respect to the power supply voltage V_{DD}.

### Second Embodiment

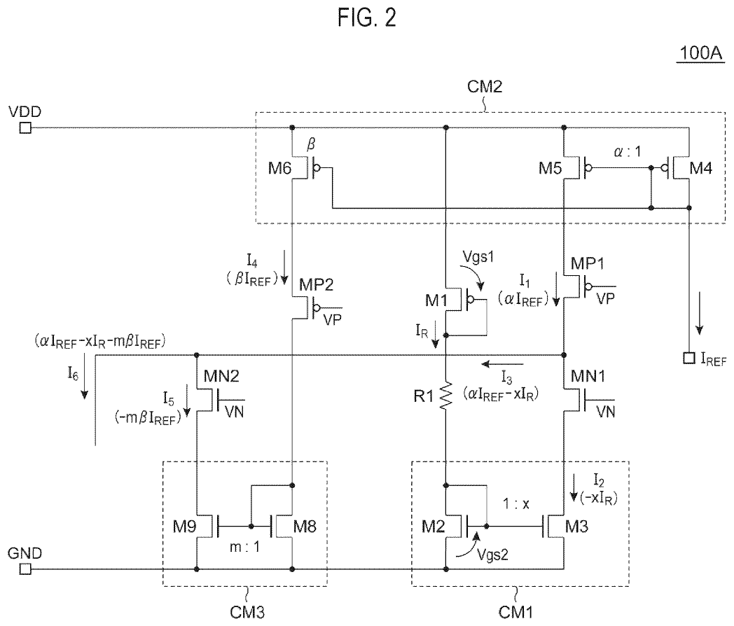

FIG. 2 is a circuit diagram of a constant current circuit 100A according to a second embodiment. Unlike the constant current circuit 100 of FIG. 1, the constant current circuit 100A further includes a third current mirror circuit CM3 and transistors MP2 and MN2. The second current mirror circuit CM2 further includes a transistor M6, and generates a fourth current I₄ by folding back the reference current I_{REF}. Using a current mirror ratio (current amplifier) β of the fourth current I₄ with respect to the reference current I_{REF}, the fourth current I₄ is expressed as I₄=β·I_{REF}.

The third current mirror circuit CM3 includes NMOS transistors M8 and M9, and folds back the fourth current I₄ to generate a fifth current I₅. Using a current amplification factor m of the third current mirror circuit CM3, the fifth current I₅ is expressed as I₅=m·I₄=m·B·I_{REF}.

The constant current circuit 100A is configured to be capable of outputting a current corresponding to a sixth current I₆ which is a difference between the third current I₃ and the fifth current I₅. The sixth current I₆ is expressed as I₆=I₃−I₅=α·I_{REF}−x·I_{R}−m·β·I_{REF}.

### Third Embodiment

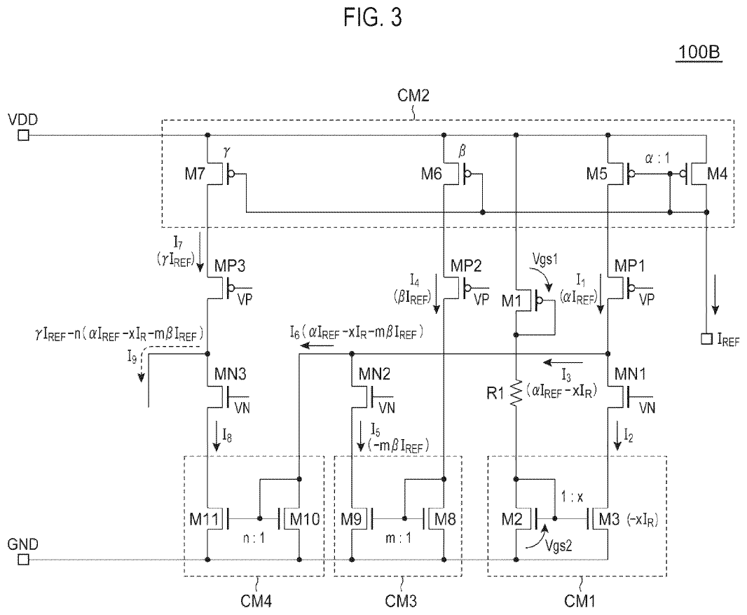

FIG. 3 is a circuit diagram of a constant current circuit 100B according to a third embodiment. Unlike the constant current circuit 100A of FIG. 2, the constant current circuit 100B further includes a fourth current mirror circuit CM4 and transistors MP3 and MN3. The second current mirror circuit CM2 further includes a transistor M7, and generates a seventh current I₇ by folding back the reference current I_{REF}. Using a current mirror ratio (current amplifier) γ of the seventh current I₇ with respect to the reference current I_{REF}, the seventh current I₇ is expressed as I₇=γ·I_{REF}.

The fourth current mirror circuit CM4 includes transistors M10 and M11, and folds back the sixth current I₆ to generate an eighth current I₈. Using a current amplification factor n of the fourth current mirror circuit CM4, the eighth current I₈ is expressed as I₈=n·I₆.

The constant current circuit 100B is configured to be capable of outputting a current corresponding to a ninth current I₉, which is a difference between the seventh current I₇ and the eighth current I₈. The ninth current I₉ is expressed as I₉=I₇−I₈=γ·I_{REF}−n (α·I_{REF}−x·I_{R}−m·β·I_{REF}).

### Fourth Embodiment

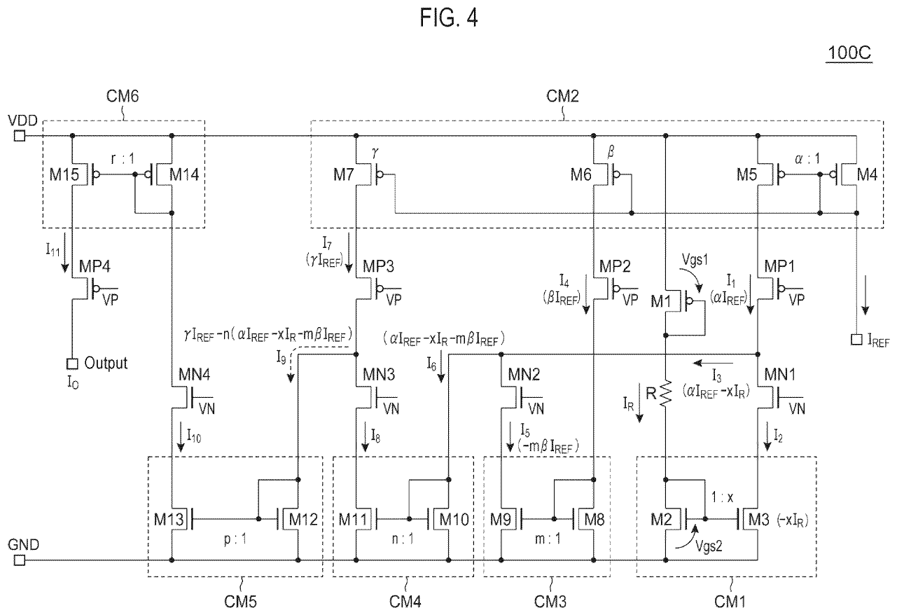

FIG. 4 is a circuit diagram of a constant current circuit 100C according to a fourth embodiment. Unlike the constant current circuit 100B of FIG. 3, the constant current circuit 100C further includes a fifth current mirror circuit CM5, a sixth current mirror circuit CM6, and transistors MP4 and MN4.

The fifth current mirror circuit CM5 includes transistors M12 and M13, and folds back the ninth current I₉ to generate a tenth current I₁₀. Using a current amplification factor p of the fifth current mirror circuit CM5, the tenth current I₁₀ is expressed as I₁₀=p. I₉.

The sixth current mirror circuit CM6 includes transistors M14 and M15, and folds back the tenth current I₁₀ to generate an eleventh current I₁₁. Using a current amplification factor r of the sixth current mirror circuit CM6, the eleventh current I₁₁ is expressed as I₁₁=r·I₁₀=r·p·I₉.

The constant current circuit 100C is configured to be capable of outputting the eleventh current I₁₁. The eleventh current I₁₁ is expressed as I₁₁=r·p·{γ·I_{REF}−n (α·I_{REF}−x·I_{R}−m·β·I_{REF})}.

Next, uses of the constant current circuits 100 to 100C (generally referred to as 100) will be described.

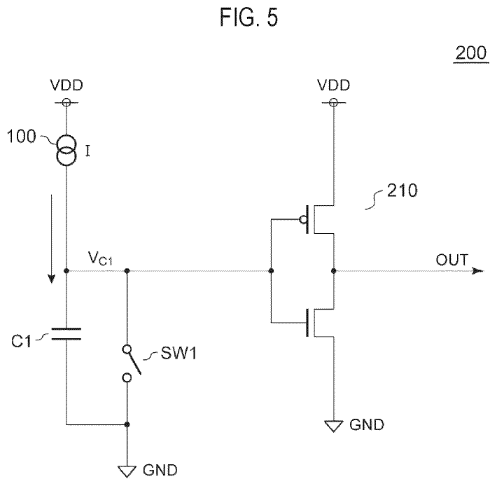

FIG. 5 is a circuit diagram of a timer circuit 200 including the constant current circuit 100. The timer circuit 200 includes the constant current circuit 100, a capacitor C1, a switch SW1, and an inverter 210. One end of the capacitor C1 is grounded. The switch SW1 is connected in parallel with the capacitor C1. The inverter 210 receives a voltage V_{C1} of the capacitor C1 and generates an output signal OUT indicating a magnitude relationship with a threshold voltage. The constant current circuit 100 supplies a charging current I to the capacitor C1.

Before the timer operates, the switch SW1 is at zero, the voltage V_{C1} of the capacitor C1 is 0 V, and the output signal OUT is high. When the timer starts, the switch SW1 is turned off. The capacitor C1 is charged by the charging current generated by the constant current circuit 100. The voltage V_{C1} of the capacitor C1 after a time t from the start of the timer is V_{C1}(t)=t×I/C1. When the voltage V_{C1} of the capacitor C1 reaches a threshold voltage V_{TH}, the output signal OUT becomes low. The time T until the voltage V_{C1} of the capacitor C1 reaches the threshold voltage V_{TH} is T=C1·V_{TH}/I.

The threshold voltage V_{TH} of the inverter 210 depends on a power supply voltage V_{DD}. The charging current I generated by the constant current circuit 100 may also be caused to have dependence on the power supply voltage V_{DD}. The measurement time T of the timer circuit 200 becomes constant without depending on the power supply voltage V_{DD} when the following relational expression holds true: I(V_{DD})=C1·V_{TH}(V_{DD})/T. In other words, the current amplification factor (current mirror ratio) and resistance value, which are parameters of the constant current circuit 100, are set so as to satisfy this relationship.

Assuming that V_{TH}(V_{DD})=V_{DD}/2, the parameters of the constant current circuit 100 may be set to satisfy the following formula: I(V_{DD})=C1·V_{DD}/(2·T).

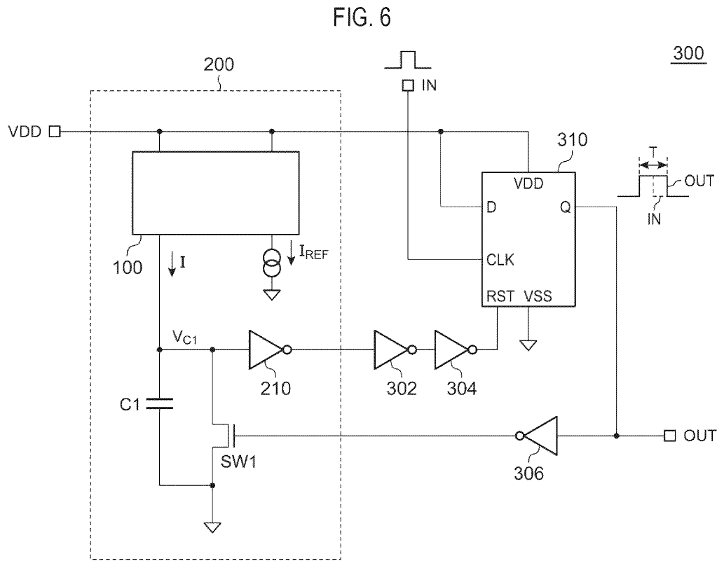

FIG. 6 is a circuit diagram of a one-shot multivibrator circuit 300 including the constant current circuit 100. The one-shot multivibrator circuit 300 receives a pulsed input signal IN and generates an output signal OUT having a constant pulse width T.

The one-shot multivibrator circuit 300 includes the timer circuit 200 of FIG. 5, inverters 302, 304, and 306, and a flip-flop 310.

A pulse signal inputted to an input terminal IN is inputted to a clock terminal (CLK) of the flip-flop 310. An output Q of the flip-flop 310 is inverted by the inverter 306 and inputted to a gate of an NMOS transistor which is the switch SW1.

An output of the timer circuit 200 is inputted to a reset terminal of the flip-flop 310 through a buffer including two stages of the inverters 302 and 304.

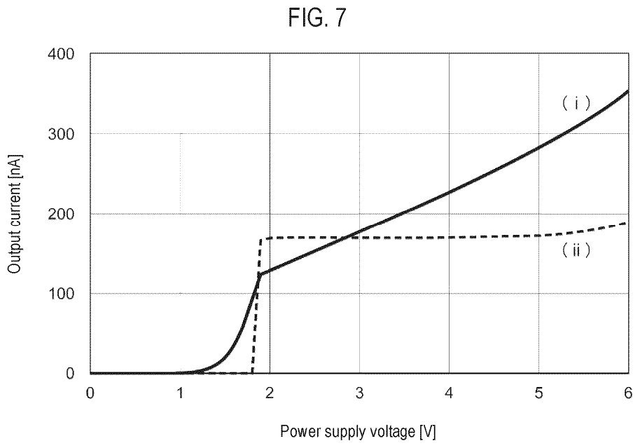

FIG. 7 is a diagram showing power supply voltage dependence of an output current I of the constant current circuit 100. Line (i) indicates characteristics when the parameters are optimally set using the constant current circuit 100C of FIG. 4. Line (ii) indicates characteristics of the charging current I in a comparative technique in which the constant current circuit 100 of FIG. 6 is configured by a simple current mirror circuit.

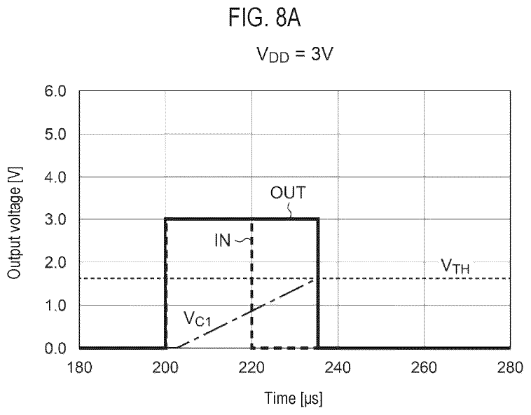

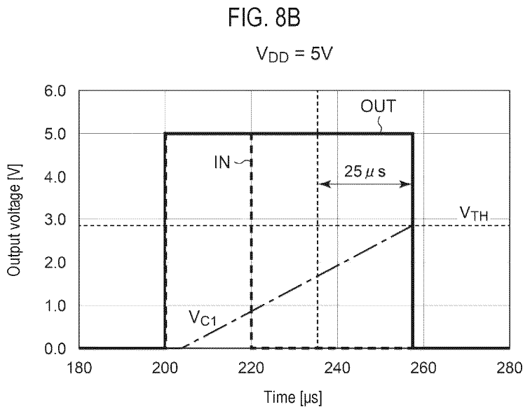

FIGS. 8A and 8B are operation waveform diagrams of the one-shot multivibrator circuit 300 when operated with the current of the comparison technique (ii) in FIG. 7. IN indicates an input signal, OUT indicates an output signal, and V_{C1} indicates the voltage of the capacitor C1. FIG. 8A shows an operation when the power supply voltage V_{DD} is 3 V, and FIG. 8B shows an operation when the power supply voltage V_{DD} is 5 V. In the comparative technique, as the power supply voltage V_{DD} increases, the pulse width of the output signal OUT increases.

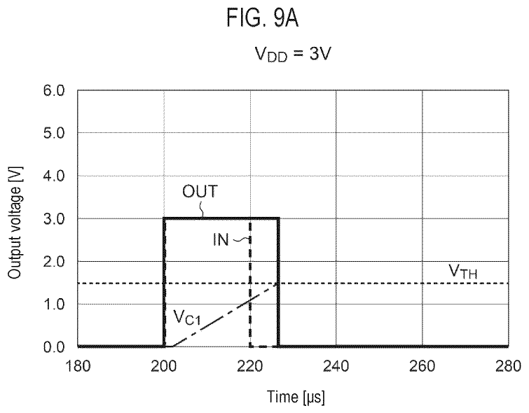

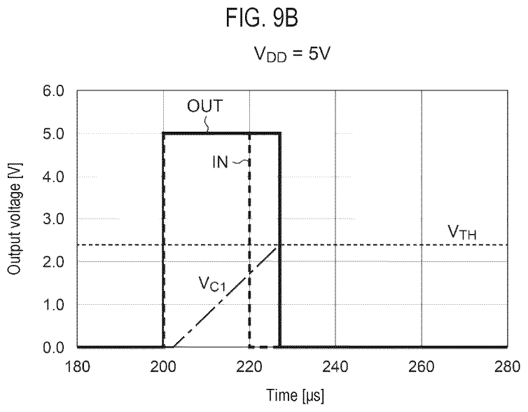

FIGS. 9A and 9B are operation waveform diagrams of the one-shot multivibrator circuit 300 when operated with the current of the embodiment (i) in FIG. 7. By using the constant current circuit 100C according to the embodiment, the pulse width of the output signal OUT becomes constant regardless of the power supply voltage V_{DD}.

Next, uses of the one-shot multivibrator circuit 300 will be described.

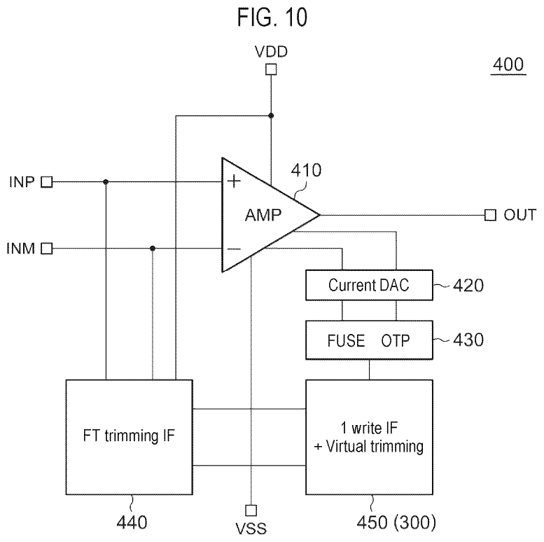

FIG. 10 is a block diagram of a semiconductor integrated circuit 400 including the one-shot multivibrator circuit 300. The semiconductor integrated circuit 400 includes an amplifier 410, a current D/A converter 420, a one-time memory circuit 430, a trimming interface circuit 440, and a trimming circuit 450.

The amplifier 410 amplifies differential input signals INP and INN. The amplifier 410 may be, for example, an operational amplifier. Alternatively, the amplifier 410 may be an amplifier circuit configured by combining an operational amplifier and a resistor, such as a subtractive amplifier circuit, a non-inverting amplifier circuit, or an inverting amplifier circuit.

The one-time memory circuit 430 is an OTP (One Time Programmable) memory. The one-time memory circuit 430 includes a plurality of fuses. Each fuse may be cut independently in a trimming process before the semiconductor integrated circuit 400 is delivered.

The current D/A converter 420 generates a current corresponding to a code stored in the one-time memory circuit 430 after fuse trimming, i.e., after programming, and supplies the current to a part of the amplifier 410. The destination to which the current is supplied is not particularly limited.

Trimming is performed using the differential input terminals INP and INN. A write pulse signal is inputted to one of the two terminals (e.g., the INP terminal). A write enable signal is inputted to the other of the two terminals (INN terminal). When the enable signal is at a first level (e.g., high level), a fuse cut mode is available, and when the enable signal is at a second level (e.g., low level), a virtual trimming mode is available.

In the trimming process, the trimming interface circuit 440 controls the trimming circuit 450 based on the states of the two input terminals INP and INN.

The trimming circuit 450 operates according to a control signal from the trimming interface circuit 440. In the fuse cut mode, the trimming circuit 450 cuts a fuse by actually supplying a current to the fuse of the one-time memory circuit 430.

The one-time memory circuit 430 enables virtual writing without actually cutting the fuse. In the virtual trimming mode, the trimming circuit 450 performs virtual writing according to the control signal from the trimming interface circuit 440. By using the virtual writing, the operation of the amplifier 410 may be checked before final writing (programming).

The trimming circuit 450 may be configured using the one-shot multivibrator circuit 300 described above. In the trimming process, the signal inputted to the INP terminal is a serial signal. The trimming circuit 450 converts this serial signal into a parallel signal using a shift register. As a result, values to be written to a plurality of fuses are held in the shift register. The output signal of the one-shot multivibrator circuit 300 may be used as a clock for this shift register.

### (Modifications)

The embodiments described above are merely examples, and those skilled in the art will understand that various modifications may be made to the combinations of the constituent elements and processing processes of the embodiments. Hereinafter, such modifications will be described.

Configurations in which the PMOS transistor and the NMOS transistor are replaced with each other and the power supply line and the ground line are reversed in FIGS. 1 to 4 are also included within the scope of the present disclosure. In this case, the second line L2 is the ground line GND, and the first line L1 is the power supply line V_{DD}.

The configuration of the one-shot multivibrator circuit 300 is not limited to that described in the embodiments, and the timer circuit according to the embodiments may be applied to various types of one-shot multivibrator circuits.

The uses of the one-shot multivibrator circuit 300 are not particularly limited, and the one-shot multivibrator circuit 300 may be used for various purposes.

Further, the constant current circuit 100 may also be given negative power supply voltage characteristics by appropriately designing the parameters. Therefore, the use of the constant current circuit 100 is not limited to the timer circuit, and the constant current circuit 100 may be used in various application circuits.

The embodiments merely illustrate the principles and applications of the present disclosure, and the embodiments may include many modifications and changes in arrangement without departing from the spirit of the present disclosure defined in the claims.

### (Supplementary Notes)

The following techniques are disclosed in this specification.

### (Item 1)

A constant current circuit, including:
a first current mirror circuit connected to a first line serving as one of a power supply line and a ground line;
a series connection circuit provided between a second line, which serves as the other of the power supply line and the ground line, and an input node of the first current mirror circuit, and including a resistor and a reference transistor, which is a MOSFET (Metal Oxide Semiconductor Field Effect Transistor) with a gate and a drain connected to each other; and
a second current mirror circuit connected to the second line and configured to generate a first current by folding back a reference current,
wherein the constant current circuit is configured to be capable of outputting a current corresponding to a third current, which is a difference between a second current outputted from the first current mirror circuit and the first current outputted from the second current mirror circuit.

### (Item 2)

The constant current circuit of Item 1, wherein the second current mirror circuit is configured to generate a fourth current by folding back the reference current,
wherein the constant current circuit further includes a third current mirror circuit configured to fold back the fourth current to generate a fifth current, and
wherein the constant current circuit is configured to be capable of outputting a current corresponding to a sixth current which is a difference between the third current and the fifth current.

### (Item 3)

The constant current circuit of Item 2, wherein the second current mirror circuit is configured to generate a seventh current by folding back the reference current,
wherein the constant current circuit further includes a fourth current mirror circuit configured to fold back the sixth current to generate an eighth current, and
wherein the constant current circuit is configured to be capable of outputting a current corresponding to a ninth current which is a difference between the seventh current and the eighth current.

### (Item 4)

The constant current circuit of Item 3, further including:
a fifth current mirror circuit configured to fold back the ninth current to generate a tenth current,
wherein the constant current circuit is configured to be capable of outputting a current corresponding to the tenth current.

### (Item 5)

The constant current circuit of Item 4, further including:
a sixth current mirror circuit configured to fold back the tenth current to generate an eleventh current,
wherein the constant current circuit is configured to be capable of outputting a current corresponding to the eleventh current.

### (Item 6)

A timer circuit, including:
a capacitor;
the constant current circuit of Item 1 configured to charge the capacitor; and
an inverter configured to receive a voltage of the capacitor.

### (Item 7)

A one-shot multivibrator circuit, including:
the timer circuit of Item 6.

### (Item 8)

A semiconductor integrated circuit, including:
a one-time memory circuit including a fuse; and
a trimming circuit including the one-shot multivibrator circuit of Item 7 configured to receive a pulse signal.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A constant current circuit, comprising:
a first current mirror circuit connected to a first line serving as one of a power supply line and a ground line;
a series connection circuit provided between a second line, which serves as the other of the power supply line and the ground line, and an input node of the first current mirror circuit, and including a resistor and a reference transistor, which is a MOSFET (Metal Oxide Semiconductor Field Effect Transistor) with a gate and a drain connected to each other; and
a second current mirror circuit connected to the second line and configured to generate a first current by folding back a reference current,
wherein the constant current circuit is configured to be capable of outputting a current corresponding to a third current, which is a difference between a second current outputted from the first current mirror circuit and the first current outputted from the second current mirror circuit.

2. The constant current circuit of claim 1, wherein the second current mirror circuit is configured to generate a fourth current by folding back the reference current,
wherein the constant current circuit further comprises a third current mirror circuit configured to fold back the fourth current to generate a fifth current, and
wherein the constant current circuit is configured to be capable of outputting a current corresponding to a sixth current which is a difference between the third current and the fifth current.

3. The constant current circuit of claim 2, wherein the second current mirror circuit is configured to generate a seventh current by folding back the reference current,
wherein the constant current circuit further comprises a fourth current mirror circuit configured to fold back the sixth current to generate an eighth current, and
wherein the constant current circuit is configured to be capable of outputting a current corresponding to a ninth current which is a difference between the seventh current and the eighth current.

4. The constant current circuit of claim 3, further comprising:
a fifth current mirror circuit configured to fold back the ninth current to generate a tenth current,
wherein the constant current circuit is configured to be capable of outputting a current corresponding to the tenth current.

5. The constant current circuit of claim 4, further comprising:
a sixth current mirror circuit configured to fold back the tenth current to generate an eleventh current,
wherein the constant current circuit is configured to be capable of outputting a current corresponding to the eleventh current.

6. A timer circuit, comprising:
a capacitor;
the constant current circuit of claim 1 configured to charge the capacitor; and
an inverter configured to receive a voltage of the capacitor.

7. A one-shot multivibrator circuit, comprising:
the timer circuit of claim 6.

8. A semiconductor integrated circuit, comprising:
a one-time memory circuit including a fuse; and
a trimming circuit including the one-shot multivibrator circuit of claim 7 configured to receive a pulse signal.
